(19) United States
(12) Patent Application Publication
(10) Pub. No.: US 2025/0273257 A1
(43) Pub. Date: Aug. 28, 2025

(54) APPARATUS INCLUDING SUBWORD DRIVERS

(71) Applicant: MICRON TECHNOLOGY, INC., Boise, ID (US)

(72) Inventors: Kyuseok Lee, Boise, ID (US); Eric J. Schultz, Boise, ID (US); Christopher G. Wieduwilt, Boise, ID (US)

(73) Assignee: MICRON TECHNOLOGY, INC., Boise, ID (US)

(21) Appl. No.: 19/035,584

(22) Filed: Jan. 23, 2025

Related U.S. Application Data
(60) Provisional application No. 63/557,174, filed on Feb. 23, 2024.

(51) Int. Cl. G11C 11/408; G11C 5/06

(52) U.S. Cl. CPC G11C 11/4085; G11C 5/063

(57) ABSTRACT

Some embodiments of the disclosure provide an apparatus comprising a first straight common gate for a plurality of first transistors of first subword drivers, a second straight common gate for a plurality of second transistors of second subword drivers, a plurality of independent gates for a plurality of bridge transistors. The first straight common gate extends straight in a first horizontal direction. The second straight common gate extends straight in the first horizontal direction and are arranged in parallel with the first straight common gate in a second horizontal direction perpendicular to the first horizontal direction. The plurality of independent gates are arranged in line between the first straight common gate and the second straight common gate.

### CROSS REFERENCE TO RELATED APPLICATION(S)

This application claims priority to U.S. Provisional Application No. 63/557,174, filed Feb. 23, 2024. The aforementioned application is incorporated herein by reference, in its entirety, for any purpose.

### BACKGROUND

High data reliability, high speed of memory access, low power consumption, and reduced chip size are some features that are demanded from a semiconductor memory device, such as a dynamic random-access memory (DRAM). A memory device includes a plurality of memory cells to store information. Memory cells may be organized at intersections of word lines and bit lines. Word lines may be arranged in an array of rows and bit lines may be arranged in an array of columns, forming a line matrix on a horizontal plane or in a plane view. During an access operation, a word line may be activated and data may be read out from memory cells along bit lines to sense amplifiers, which may detect the information stored in the memory cells.

A semiconductor memory device may include hierarchically structured main word lines and word lines. The main word line is driven by a respective main word driver and is positioned at an upper hierarchy, and is selected by a first portion of a row address. The word line is driven by a respective subword driver (or subword line driver) and is positioned at a lower hierarchy, and is selected based on a corresponding main word line and a word driver line selected by a second portion of the row address.

Since a plurality of subword drivers are repeatedly arranged for the word lines in the respective rows, a layout of each subword driver, such as a driver height, has a significant impact on the device die size as well as the device cost. There is, hence, a demand for further effectively decreasing the subword driver dimensions in order to achieve the desired device scaling.

### BRIEF DESCRIPTION OF THE DRAWINGS

FIG. 1 is a block diagram of an example semiconductor device according to an embodiment of the disclosure.

FIG. 2 is a schematic diagram of an example subword driver configuration according to an embodiment of the disclosure.

FIG. 3 depicts an example layout of subword drivers including active regions, a gate layer, and an interconnect layer in a plan view according to an embodiment of the disclosure.

FIGS. 4A-C depict an example layer layout of at least part of an apparatus in a play view according to an embodiment of the disclosure.

### DETAILED DESCRIPTION

Various example embodiments of the disclosure will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, some of the same signs may be omitted for the same or substantially the same elements for ease of illustration. In the drawings, the dimensions and dimensional ratios of each unit do not necessarily match the actual dimensions and dimensional ratios in the embodiments.

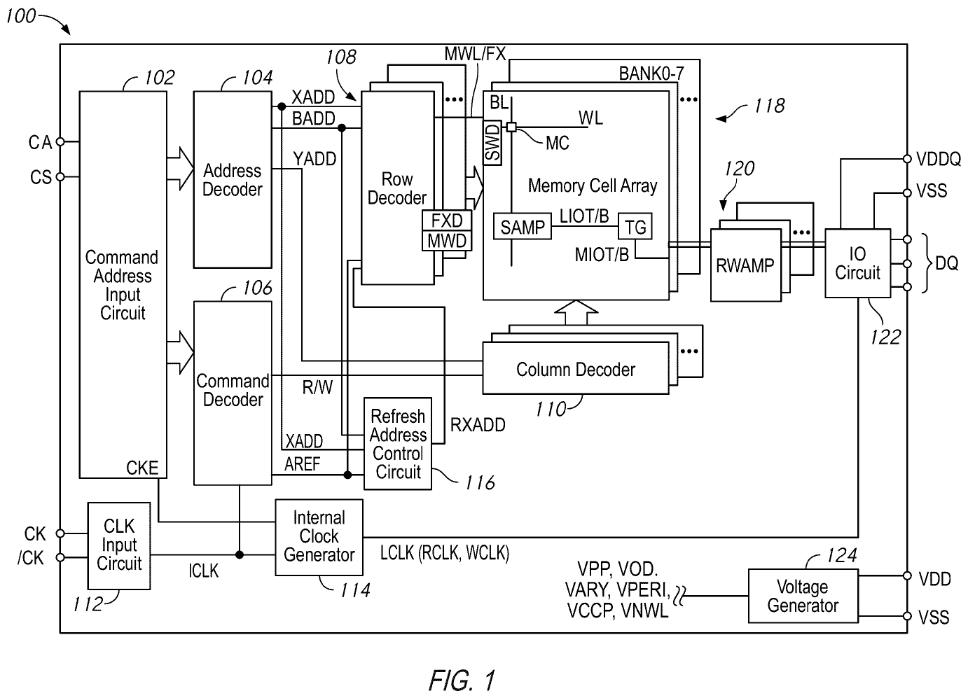

FIG. 1 is a block diagram of an example semiconductor device 100 according to an embodiment of the disclosure. The semiconductor device 100 may be a semiconductor memory device, such as a dynamic random access memory (DRAM). The semiconductor device 100 includes a memory array 118. The memory array 118 is shown as including a plurality of memory banks. In the embodiment of FIG. 1, the memory array 118 is shown as including eight memory banks BANK0-BANK7. More or fewer banks may be included in the memory array 118 of other embodiments. Each memory bank includes a plurality of word lines WL, a plurality of bit lines BL, and a plurality of memory cells MC arranged at intersections of the plurality of word lines WL and the plurality of bit line BL. Selection of the word line WL is performed by a row decoder 108 and selection of the bit lines BL is performed by a column decoder 110. In the embodiment of FIG. 1, the row decoder 108 includes a respective row decoder for each memory bank and the column decoder 110 includes a respective column decoder for each memory bank. The bit lines BL are coupled to a respective sense amplifier (SAMP) of the memory array 118. Read data from the bit line BL is amplified by the sense amplifier SAMP, and transferred to read/write amplifiers (RWAMPs) 120 over complementary local data lines (LIOT/B), transfer gate (TG), and complementary main data lines (MIOT/B) which are coupled to RWAMP 120. Conversely, write data outputted from RWAMP 120 is transferred to the sense amplifier SAMP over the complementary main data lines MIOT/B, the transfer gate TG, and the complementary local data lines LIOT/B, and written in the memory cell MC coupled to the bit line BL.

The semiconductor device 100 may employ a plurality of external terminals that include command and address (CA) terminals coupled to a command and address bus to receive commands and addresses and a chip select (CS) signal, clock terminals to receive clocks CK and/CK, data terminals DQ to provide data, and power supply terminals to receive power supply potentials VDD, VSS, and VDDQ.

The clock terminals are supplied with external clocks CK and/CK that are provided to an input circuit 112. The external clocks CK and/CK may be complementary. The input circuit 112 generates an internal clock ICLK based on the CK and/CK clocks. The ICLK clock is provided to the command decoder 106 and to an internal clock generator 114. The internal clock generator 114 provides various internal clocks LCLK based on the ICLK clock. The LCLK clocks may be used for timing operation of various internal circuits. The internal clocks LCLK are provided to an input and output (IO) circuit 122 to time operation of circuits included in the IO circuit 122, for example, to data receivers to time the receipt of write data.

The internal clocks LCLK may include a read clock (RCLK) which is used to control the timing of read operations, and a write clock (WCLK) which is used to control the timing of write operations. The internal clocks may be passed to the IO circuit 122. In some instances, the internal clocks may also be passed to internal components, such as RWAMP 120.

The CA terminals may be supplied with memory addresses. The memory addresses supplied to the CA terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The CA terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to the command decoder 106 via the command/address input circuit 102. The command decoder 106 includes circuits to decode the internal command signals to generate various internal signals and commands for performing operations. For example, the command decoder 106 may provide a row command signal to select a word line and a column command signal to select a bit line.

The semiconductor device 100 may receive an access command which is a read command. When a read command is received, and a bank address, a row address and a column address are timely supplied with an activate command and the read command, read data is read from memory cells in the memory array 118 corresponding to the row address and column address. The read command is received by the command decoder 106, which provides internal commands so that the read data from the memory cells in the memory array 118 is provided to RWAMP 120. The read data is output to outside the semiconductor device 100 from the data terminals DQ via the IO circuit 122.

The semiconductor device 100 may receive an access command which is a write command. When the write command is received, and a bank address, a row address and a column address are timely supplied with an activate command and the write command, write data is supplied through the DQ terminals to RWAMP 120. The write data supplied to the data terminals DQ is written to the memory cells in the memory array 118 corresponding to the row address and column address. The write command is received by the command decoder 106, which provides internal commands so that the write data is received by data receivers in the IO circuit 122. Write clocks may also be provided to the external clock terminals for timing the receipt of the write data by the data receivers of the IO circuit 122. The write data is supplied via the IO circuit 122 to RWAMP 120.

The semiconductor device 100 may also receive commands causing it to carry out one or more refresh operations as part of a self-refresh mode. In some embodiments, the self-refresh mode command may be externally issued to the semiconductor device 100. In some embodiments, the self-refresh mode command may be periodically generated by a component of the device. In some embodiments, when an external signal indicates a self-refresh entry command, the refresh signal AREF may also be activated.

The power supply terminals are supplied with power supply potentials VDD and VSS. The power supply potentials VDD and VSS are supplied to an internal voltage generator circuit 124. The internal voltage generator circuit 124 generates various internal potentials such as VPP, VOD, VARY, VPERI, VCCP, VNWL, and the like based on the power supply potentials VDD and VSS.

The power supply terminals are also supplied with power supply potential VDDQ. The power supply potential VDDQ is supplied to the IO circuit 122. The power supply potential VDDQ may be the same potentials as the power supply potential VDD in one embodiment of the disclosure. The power supply potential VDDQ may be different potentials from the power supply potential VDD in another embodiment of the disclosure. The power supply potential VDDQ are used for the IO circuit 122 so that power supply noise generated by the IO circuit 122 does not propagate to the other circuit blocks.

In some embodiments of the disclosure, the plurality of memory cells MC form a memory cell array in each memory bank of the memory array 118. The memory cell array may include a plurality of memory mats (not separately depicted in FIG. 1). The memory cell array may be divided into a plurality of memory mats. Each memory mat has a group of word lines WL and bit lines BL assigned thereto. In the assigned group, an array of the word lines WL extends in one direction, and an array of the bit lines BL extends in another direction. Each line extends through the memory mat to an outside area of the memory mat. In the outside area of the memory mat, subword drivers (or subword line drivers) SWD may be coupled to the word lines WL in the respective rows, and sense amplifiers SAMP may be coupled to the bit lines BL in the respective columns. In one example, subword driver SWD blocks may be disposed on two sides of the memory mat in the first horizontal direction, and sense amplifier SAMP blocks may be disposed on two sides of the memory mat in the second horizontal direction. The memory mat may also be referred to as a memory array mat.

The word lines WL may be driven by the subword drivers SWD. For clarity, only one WL and SWD in the memory cell array of one memory bank are shown in FIG. 1. A plurality of main word lines MWL and word driver lines FX may be provided to respective subword drivers SWD. Selection of a main word line MWL and a word driver line FX may be carried out by the row decoder 108. A plurality of word drivers FXD and main word drivers MWD may be included in respective row decoders 108. The word driver lines FX may be driven by the respective word drivers FXD. The main word lines MWL may be driven by the respective main word drivers MWD. For example, a memory device may have 128 main word lines and 128 main word drivers providing respective main word lines.

The internal potentials VCCP and VNWL generated by the internal voltage generator circuit 124 may be mainly used in the row decoder circuit 108, the main word drivers MWD, and the word drivers FXD. For example, a word driver FXD, when selected among the plurality of word drivers FXD based upon the decoded row address XADD, may be configured to drive a potential on the word driver line FX to a VCCP level corresponding to a high potential (e.g., 3.1 V). As one example operation, when a row is in pre-charge state, an associated subword driver SWD, responsive to an inactive signal on the main word line MWL and an inactive signal on the word driver line FX, may be configured to pull down the word line WL to the internal voltage VNWL (e.g., a non-active potential, which may be a negative voltage).

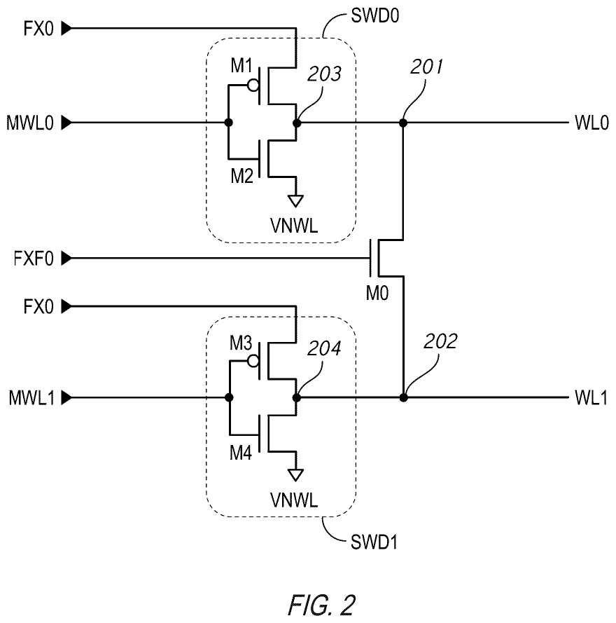

FIG. 2 is a schematic diagram of an example subword driver configuration according to an embodiment of the disclosure. The example subword driver configuration includes two subword drivers SWD0 and SWD1 coupled to two adjacent word lines WL0 and WL1, respectively. The example subword driver configuration further includes a transistor M0 coupled to a common terminal 201 of the subword driver SWD0 and the word line WL0 and another common terminal 202 of the subword driver SWD1 and the word line WL1, bridging the two adjacent word lines WL0 and WL1. The transistor M0 may be referred to as “a bridge transistor.” The subword drivers SWD0 and SWD1 are configured to drive the word lines WL0 and WL1, respectively, based on, for example, signals provided via main word lines MWL0 and MWL1 and a word driver line FX0. Each of the subword drivers SWD0 and SWD1 includes a pair of two transistors M1-M2 or M3-M4. Together with the bridge transistor M0, the example configuration includes five transistors to drive two word lines (e.g., which may include two adjacent word lines). The example configuration may therefore be referred to as 2.5 transistor-wordline configuration.

The subword drivers SWD0 and SWD1 have the same circuit configuration. The subword driver SWD0 includes two transistors M1 and M2 coupled to each other in series. The transistors M1 and M2 may be metal-oxide-semiconductor (MOS) field-effect transistors of different conductivity types. M1 is a p-channel type MOS transistor (hereinafter may also be referred to as a PMOS transistor) and M2 is an n-channel type MOS transistor (hereinafter may also be referred to as an NMOS transistor), constituting a complementary MOS (CMOS) transistor pair. A source of M1 is coupled to the word driver line FX0 to receive a word driver signal. A source of M2 is coupled to the internal non-active potential VNWL. Drains of M1 and M2 are commonly coupled to an output terminal 203 of the subword driver SWD0. The output terminal 203 is coupled to the word line WL0 through the common terminal 201. Gates of M1 and M2 are commonly coupled to the main word line MWL0 to receive a main word line signal. The word driver signal and the main word line signal may be generated and provided by the word driver FXD and the main word driver MWD of the row decoder 108 in FIG. 1, respectively, based on at least the decoded row address XADD for the subword driver SWD0 and the word line WL0. The PMOS transistor M1 may be a pull up device to pull up the word line WL0 to the higher internal potential, such as VCCP, and turn on the word line WL0. The NMOS transistor M2 may be a pull down device to pull down the word line WL0 to the internal non-active potential VNWL.

The subword driver SWD1 includes two transistors M3 and M4 coupled to each other in series. The transistors M3 and M4 may be MOS field-effect transistors of different conductivity types. M3 is a PMOS transistor and M4 is an NMOS, constituting a CMOS transistor pair. A source of M3 is coupled to the word driver line FX0 to receive the word driver signal. A source of M4 is coupled to the non-active potential VNWL. Drains of M3 and M4 are commonly coupled to an output terminal 204 of the subword driver SWD1. The output terminal 204 is coupled to the word line WL1 through the common terminal 202. Gates of M3 and M4 are commonly coupled to the main word line MWL1 to receive a main word line signal. The word driver signal and the main word line signal may be generated and provided by the word driver FXD and the main word driver MWD of the row decoder 108 in FIG. 1, respectively, based on at least the decoded row address XADD for the subword driver SWD1 and the word line WL1. Similarly to M1 and M2 of the subword driver SWD0, the PMOS transistor M3 may be a pull up device to pull up the word line WL1 to the higher internal potential, such as VCCP, and turn on the word line WL1. The NMOS transistor M4 may be a pull down device to pull down the word line WL1 to the internal non-active potential VNWL.

The bridge transistor M0 is an NMOS transistor. M0 is bridged between the common terminal 201 of the subword driver SWD0 and the word line WL0 and the common terminal 202 of the subword driver SWD1 and the word line WL1. A source/drain of M0 is coupled to the common terminal 201, which is coupled to the output terminal 203 of SWD0. Another source/drain of M0 is coupled to the common terminal 202, which is coupled to the output terminal 204 of SWD1. A gate of M0 is coupled to a gate control line FXF0 to receive a gate control signal. The gate control signal may be complementary to the word driver signal on the word driver line FX0. For example, the complementary gate control signal may be an inverse of the word driver signal. The gate control signal on FXF0 may be generated by the row decoder 108. Hereinafter, the reference characters FX0, MWL0, MWL1, and FXF0 may be interchangeably used to indicate the respective lines and the respective signals. In one example operation, when an active word driver signal FX0 (e.g., active high logic level) is provided to the subword driver SWD0 selected by MWL0 and to the subword driver SWD1 selected by MWL1, at the same time, the gate control signal FXF0 (which is complementary to the word driver signal FX0) turns off the bridge transistor M0.

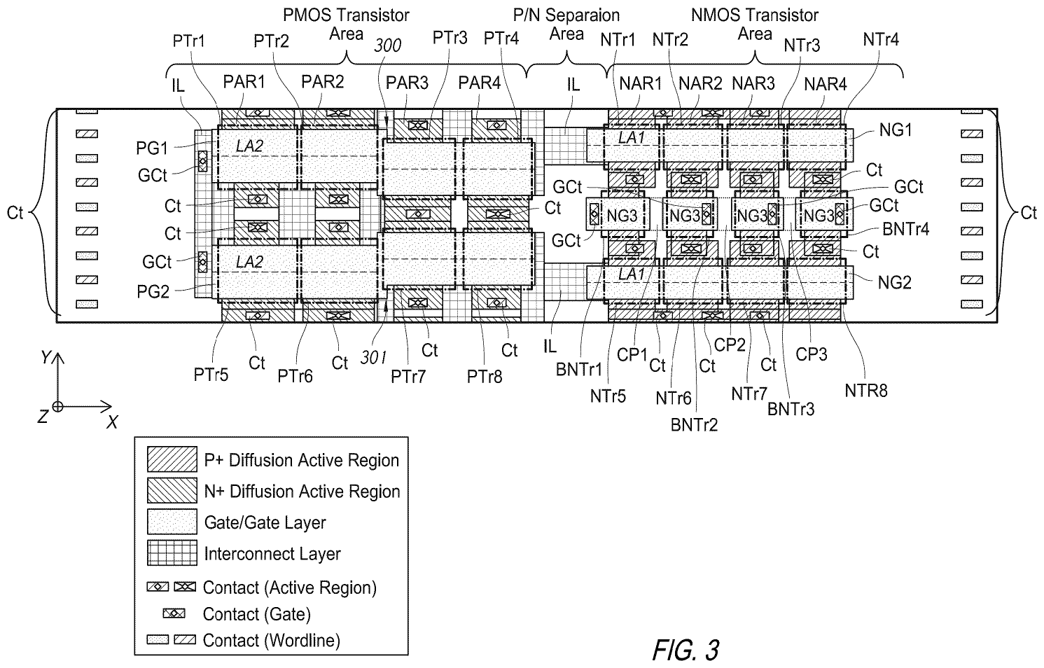

FIG. 3 depicts an example layout of subword drivers including active regions, a gate layer, and an interconnect layer in a plan view according to an embodiment of the disclosure. The example layout includes a PMOS transistor area and an NMOS transistor area adjacent to each other with a P/N separation area between the two areas.

The PMOS transistor area includes a plurality of active regions PARn (n=integer), e.g., PAR1-4, having P+ diffusion materials and implements a plurality of PMOS transistors PTrn (n=integer), e.g., PTr1-4 and PTr5-8, of the subword drivers SWD. The active regions PARn may include one or more drains, sources, and channels of the PMOS transistors PTrn. The NMOS transistor area includes a plurality of active regions NARn (n=integer), e.g., NAR1-4, having N+ diffusion materials and implements a plurality of NMOS transistors NTrn/BNTrn (n=integer), e.g., NTr1-4, NTr5-8, and BNTr1-4, of the subword drivers SWD. The active regions NARn may include one or more drains, sources, and channels of the NMOS transistors NTrn/BNTrn.

In the PMOS transistor area of the example layout, the active regions PAR1-4 are arranged at predetermined positions in a plan view such that the PMOS transistors PTr1-4 are implemented in one row (a first PTr row) in one horizontal direction (that is, for example, a horizontal direction along X-axis in the drawing, and may be referred to as an X-axis direction herein). Similarly, the other active regions are positioned such that the PMOS transistors PTr5-8 are in another row (a second PTr row) parallel to the first PTr row in another horizontal direction (that is, for example, a horizontal direction along Y-axis perpendicular to X-axis in the drawing, and may be referred to as a Y-axis direction herein). In the NMOS transistor area, the active regions NAR1-4 are arranged at predetermined positions in the plan view such that the NMOS transistors NTr1-4 align in one row (a first NTr row) in the X-axis direction. Similarly, the other active regions are positioned such that the NMOS transistors NTr5-8 are in another row (a second NTr row) parallel to the first NTr row, and the further active regions are positioned such that the bridge NMOS transistors BNTr1-4 align in still another row (a BNTr row) between the first and second NTr rows. The PMOS transistor area and the NMOS transistor area may have any suitable number of active regions. In FIG. 3, not all of the active regions are annotated with PARn and NARn for the sake of simplicity; however, the same or similar shaded regions illustrate the active regions. In FIG. 3, PTr1-8, NTr1-8, and BNTr1-4 are indicated with dashed-line rectangles; however, the areas of the dashed-line rectangles are not limited to those as illustrated. They may include broader areas, may include contacts (which will be described in detail below), and/or may overlap with each other where appropriate.

The example layout further includes one or more gate layers overlaid on the active regions to form gates of the PMOS transistors in the PMOS transistor area and to form gates of the NMOS transistors and the bridge NMOS transistors in the NMOS transistor area. The gate layers may include polycrystalline silicon or polysilicon (poly-Si). Each gate layer may be a gate poly-Si layer. In the example layout, the PMOS transistor area includes gates PG1 and PG2 each extending in the X-axis direction and arranged in parallel with each other in the Y-axis direction. The gate PG1 and the gate PG2 are shared by corresponding groups of the PMOS transistors. For example, PG1 is shared by the group of PTr1-4, and PG2 is shared by the group of PTr5-8. Similarly, the NMOS transistor area includes gates NG1 and NG2 each extending in the X-axis direction and arranged in parallel with each other in the Y-axis direction. The gate NG1 and the gate NG2 are shared by corresponding groups of the NMOS transistors. For example, NG1 is shared by the group of NTr1-4, and NG2 is shared by the group of NTr5-8. The gates PG1-2 and NG1-2 may hence be referred to as common gates.

In the example layout, unlike the common gates PG1-2 which include some bent or stepped portions 300 and 301 in the middle thereof in the X-axis direction, the common gates NG1-2 in the NMOS transistor area each extend straight in the X-axis direction without any bent or stepped portions. Each of the common gates NG1-2 has a strip-like form in the plan view including first and second longitudinal sides that extend uniformly from one end to another end of the common gate in the X-axis direction. In each of the common gates NG1-2, a longitudinal axis LA1 halfway between the first and second longitudinal sides is continuous from one end to another end. In contrast, a longitudinal axis LA2 halfway between two longitudinal sides of each of the common gates PG1-2 is discontinuous (i.e., discontinuous at the bent portions 300 and 301). The NMOS transistors hence have a gate with a “straight gate” formation. The common gates NG1-2 may also be referred to as straight common gates.

In the example layout, the NMOS transistor area further includes a plurality of gates NG3 arranged in line in the X-axis direction and between the straight common gates NG1-2 in the Y-axis direction. While arranged in line in the X-axis direction along NG1-2, NG3 are separated from one another by cut portions CP1-3 therebetween to form separate independent gates for the respective bridge NMOS transistors BNTr1-4 in such a manner that they are not shorted. The gates NG3 may hence be referred to as independent gates. For example, CP1 separates the independent gates NG3 of BNTr1 and BNTr2, CP2 separates the independent gates NG3 of BNTr2 and BNTr3, and CP3 separates the independent gates NG3 of BNTr3 and BNTr4. The cut portions CP1-3 may also be referred to as poly-cut portions or poly-cut breaks in the case where the gate layer which provides the independent gates NG3 is a poly-Si layer. As one example process, after the entire gate layer is formed over the active regions, the cut portions CP1-3 may be formed by appropriate photolithography, etching, and the like to cut or break the gate layer at predetermined positions. In the example layout including the gate arrangement as described, the group of the NMOS transistors NTr1-4 with the straight common gate NG1 in the first NTr row and the group of the NMOS transistors NTr5-8 with the straight common gate NG2 in the second NTr row parallel to the first NTr row share the four bridge transistors BNTr1-4 having the four independent gates NG3 in the BNTr row between the first and second NTr rows.

According to the present embodiments, the straight gate formation of each of the common gates of the NMOS transistors together with the independent gates of the bridge NMOS transistors in the NMOS transistor area realizes a reduction of the size of each subword driver SWD, such as a driver size in the X-axis direction in the drawing. As one example, some tens of nanometers in the transistor gate size in the X-axis direction can be reduced, which in turn achieves the further reduction of the subword driver. Consequently, this reduces the size of the memory array in a semiconductor device, such as the semiconductor device 100 of FIG. 1, and increases the array efficiency.

Still referring to FIG. 3, the example layout further includes at least one interconnect layer IL overlaid above the active regions or the gate layers. The interconnect layer IL may couple the gates PG1-2 in the PMOS transistor area and the straight gates NG1-2 in the NMOS transistor area. For example, PG1 and NG1 are coupled to each other and PG2 and NG2 are coupled to each other via one or more interconnect layers IL.

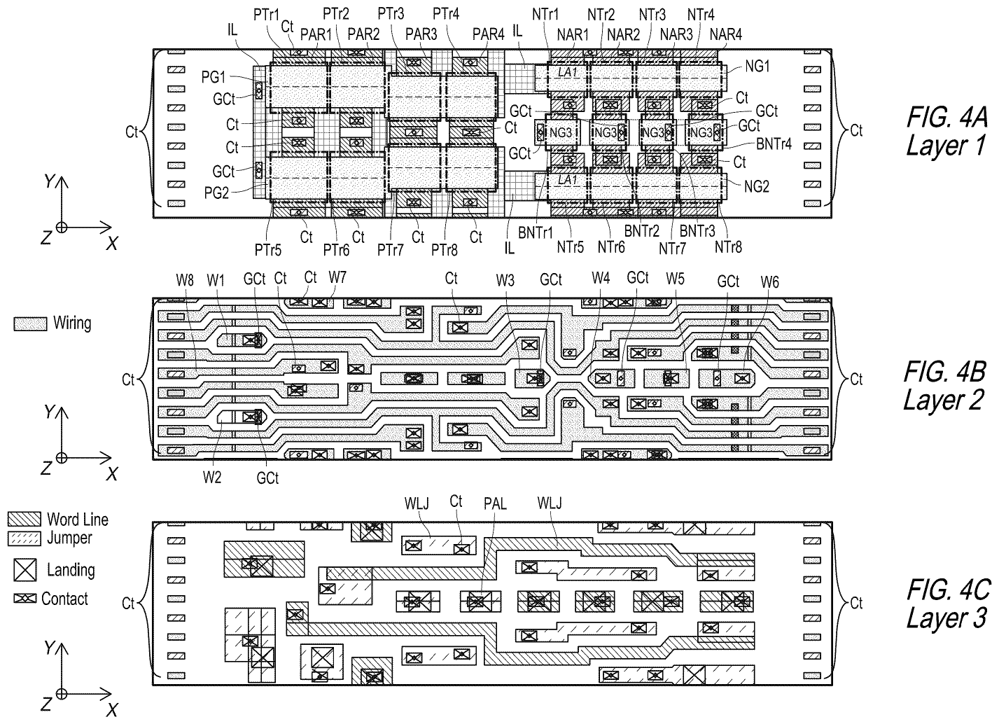

In the example layer layout, the gates PG1-2 of the PMOS transistors PTr1-8 and the gates NG1-2 of the NMOS transistors NTr1-8 may be coupled to main word lines, such as MWL0 and MWL1 in the schematic of FIG. 2, via the gate contacts GCt. For example, the common gate PG1 of PTr1-4 and the common gate NG1 of NTr1-4 are coupled to each other via the interconnect layer IL as described above with respect to FIG. 3, and these common gates PG1 and NG1 may be commonly coupled to one main word line (e.g., MWL0 in FIG. 2) via one gate contact GCt that is provided at one edge area of the interconnect layer IL adjacent to one end portion of PG1 in the X-axis direction. Similarly, the common gate PG2 of PTr4-8 and the common gate NG2 of NTr4-8 may be commonly coupled to another main word line (e.g., MWL1 in FIG. 2) via another gate contact GCt that is provided at the edge area of the interconnect layer IL adjacent to one end portion of PG2 in the X-axis direction. The gate contacts GCt extend in the Z-axis direction from Layer 1 (FIG. 4A) to Layer 2 (FIG. 4B), and are coupled to wirings W1 and W2 which may be provided in the metal layer in Layer 2. In one instance, the wirings W1 and W2 may include at least part of the main word lines. In another instance, the wirings W1 and W2 may be coupled to the main word lines.

FIGS. 4A-C depict an example layer layout of at least part of an apparatus in a plan view according to an embodiment of the disclosure. The apparatus may be a semiconductor device. The semiconductor device may be a DRAM. The semiconductor device may include or constitute at least part of the semiconductor device 100 of FIG. 1. The example layer layout includes Layers 1-3 of FIGS. 4A-C which may be stacked on one another and constitute a multi-layer structure on a semiconductor substrate. Each of Layers 1-3 may include a plurality of layers or sub-layers stacked on one another. Layer 1 of FIG. 4A may correspond to the example layout of FIG. 3. Layers 2 and 3 of FIGS. 4B and 4C may be layered above Layer 1. Layer 2 may be stacked on Layer 1 and may include a metal layer and an interconnect layer stacked on one another. The metal layer may include one or more metal layers. The interconnect layer may include one or more interconnect layers. The metal layer may include various wirings. The wirings may include main word lines, word driver lines, gate control lines, word lines, and such. The interconnect layer may include contacts. The contacts may include active region contacts, gate contacts, word line contacts, and such. Layer 2 may further include a power and addressing redistribution layer. Layer 3 may be stacked on Layer 2 and may include a further interconnect layer. The interconnect layer may include one or more interconnect layers. The interconnect layer may include word line jumpers and further contacts. Layer 3 may further include power and addressing landings. Layers 1-3 may include other elements than those illustrated in FIGS. 4A-4B as appropriate.

In the example layer layout, the gates PG1-2 of the PMOS transistors PTr1-8 and the gates NG1-2 of the NMOS transistors NTr1-8 may be coupled to main word lines, such as MWL0 and MWL1 in the schematic of FIG. 2, via the gate contacts GCt. For example, the common gate PG1 of PTr1-4 and the common gate NG1 of NTr1-4 are coupled to each other via the interconnect layer IL as described above with respect to FIG. 3, and these common gates PG1 and NG1 may be commonly coupled to one main word line (e.g., MWL0 in FIG. 2) via one gate contact GCt that is provided at one edge area of the interconnect layer IL adjacent to one end portion of PG1 in the X-axis direction. Similarly, the common gates PG2 and NG2 of PTr4-8 and NTr4-8 may be commonly coupled to another main word line (e.g., MWL1 in FIG. 2) via another gate contact GCt that is provided at the edge area of the interconnect layer IL adjacent to one end portion of PG2 in the X-axis direction. The gate contacts GCt extend in the Z-axis direction from Layer 1 (FIG. 4A) to Layer 2 (FIG. 4B), and are coupled to wirings W1 and W2 which may be provided in the metal layer in Layer 2. In one instance, the wirings W1 and W2 may include at least part of the main word lines. In another instance, the wirings W1 and W2 may be coupled to the main word lines.

Also, the gates NG3 of the bridge NMOS transistors BNTr-4 may be coupled to gate control lines, such as FXF0 in the schematic of FIG. 2, via the gate contacts GCt of the respective gates NG3. For example, one independent gate NG3 of the bridge NMOS transistor BNTr1 may be coupled to one gate control line (e.g., FXF0 in FIG. 2) via one gate contact GCt provided in the interconnect layer at a position corresponding to the independent gate NG3. In a similar manner to the gate contacts GCt for the common gates PG1-2 and NG1-2, the gate contact GCt for the independent gate NG3 extends in the Z-axis direction from Layer 1 (FIG. 4A) to Layer 2 (FIG. 4B) and is coupled to a wiring W3 which may be provided in the metal layer in Layer 2. The wiring W3 may include at least part of or may be coupled to the gate control line. The same configuration may apply to coupling of the rest of the gates NG3 of the bridge NMOS transistors BNTr2-4 to the corresponding gate control lines via the corresponding gate contacts GCt and wirings W4-6.

The active regions which may include sources and drains of the PMOS transistors PTr1-8, the NMOS transistors NTr1-8, and the bridge NMOS transistor BNTr1-4 may be coupled to corresponding word driver lines and word lines, such as FX0 and WL0-1 in the schematic of FIG. 2, via the contacts Ct of the respective active regions. For example, the active region PAR1 of PTr1 may be coupled to one word driver line (e.g., FX0 in FIG. 2) via one contact Ct provided in the interconnect layer at a position corresponding to the active region PAR1. Like the gate contacts GCt described above, the contact Ct extends in the Z-axis direction from Layer 1 (FIG. 4A) to Layer 2 (FIG. 4B) and is coupled to a wiring W7 which may be provided in the metal layer in Layer 2. The wiring W7 may include at least part of or may be coupled to the word driver line. Furthermore, the same active region PAR1 may be coupled to one word line (e.g., WL0 in FIG. 2) via another contact Ct and another wiring W8. In one instance, the wiring W8 may include at least part of or may be coupled to the word line. In another instance, the wiring W8 may be coupled to another contact Ct, which may then be coupled to the word line. The same configuration may apply to coupling of the rest of the active regions of the PMOS transistors PTr2-8 and the NMOS and bridge NMOS transistors NTr1-8 and BNTr1-4 to the corresponding word driver lines and word lines via the corresponding contacts Ct and wirings. Some contacts in Layer 2 may further be extended into Layer 3 (FIG. 4C) and coupled to other contacts or interconnect layers in Layer 3, which may then be coupled to other elements, such as word line jumpers WLJ and power/addressing landings PAL. With such couplings of the active regions and the gates via the various contacts to the corresponding word driver lines (e.g., FX0), main word lines (e.g., MWL0-1), gate control lines (e.g., FXF0) and word lines (e.g., WL0-1), a subword driver configuration, such as the one illustrated in FIG. 2, may be realized for every two word lines.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still fall within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. An apparatus, comprising:
a first straight common gate for a plurality of first transistors of first subword drivers, the first straight common gate extending straight in a first horizontal direction;
a second straight common gate for a plurality of second transistors of second subword drivers, the second straight common gate extending straight in the first horizontal direction and arranged in parallel with the first straight common gate in a second horizontal direction perpendicular to the first horizontal direction; and
a plurality of independent gates for a plurality of bridge transistors, the plurality of independent gates arranged in line between the first straight common gate and the second straight common gate.

2. The apparatus according to claim 1, wherein the first transistors of the first subword drivers, the second transistors of the second subword drivers, and the bridge transistors are n-channel type transistors.

3. The apparatus according to claim 1, wherein
the first straight common gate is shared by the first transistors of the first subword drivers, and
the second straight common gate is shared by the second transistors of the second subword drivers.

4. The apparatus according to claim 1, wherein
the first straight common gate extends straight in the first horizontal direction over a plurality of first active regions for the first transistors of the first subword drivers, and
the second straight common gate extends straight in the first horizontal direction over a plurality of second active regions for the second transistors of the second subword drivers.

5. The apparatus according to claim 1, wherein
the first straight common gate includes longitudinal sides that extend uniformly from one end to another end of the first straight common gate in the first horizontal direction, and
the second straight common gate includes longitudinal sides that extend uniformly from one end to another end of the second straight common gate in the first horizontal direction.

6. The apparatus according to claim 1, wherein
the first straight common gate is coupled to a first main word line, and
the second straight common gate is coupled to a second main word line.

7. The apparatus according to claim 1, wherein the plurality of independent gates are arranged in a row in the first horizontal direction and in parallel with the first and second straight common gates.

8. The apparatus according to claim 1, wherein the plurality of independent gates are arranged on a plurality of active regions for the plurality of bridge transistors.

9. The apparatus according to claim 1, wherein each of the plurality of independent gates is configured to receive a gate control signal complementary to a word driver signal of the first and second subword drivers.

10. The apparatus according to claim 1, wherein
the first straight common gate, the second straight common gate, and the independent gates are in a polysilicon gate layer, and
the independent gates are separated from one another by a cut portion in the polysilicon gate layer.

11. The apparatus according to claim 1, wherein
one of a source and a drain of one bridge transistor of the plurality of bridge transistors is coupled to a first word line and a first output terminal of a corresponding first subword driver of the plurality of first subword drivers, the corresponding first subword driver configured to drive the first word line, and
another of the source and the drain of the one bridge transistor is coupled to a second word line and a second output terminal of a corresponding second subword driver of the plurality of second subword drivers, the corresponding second subword driver configured to drive the second word line.

12. The apparatus according to claim 11, wherein
a drain of a transistor of the corresponding first subword driver is coupled to the first word line via the first output terminal, and
a drain of a transistor of the corresponding second subword driver is coupled to the second word line via the second output terminal.

13. An apparatus, comprising:
a first straight common gate shared by a plurality of first transistors of first subword drivers, the first straight common gate extending straight in a first horizontal direction over a plurality of first active regions of the first transistors;
a second straight common gate shared by a plurality of second transistors of second subword drivers, the second straight common gate extending straight in the first horizontal direction over a plurality of second active regions of the second transistors and arranged in parallel with the first straight common gate in a second horizontal direction perpendicular to the first horizontal direction; and
a plurality of independent gates for a plurality of bridge transistors, the plurality of independent gates arranged in a row in the first horizontal direction over a plurality of active regions of the bridge transistors, and between the first straight common gate and the second straight common gate in parallel therewith.

14. The apparatus according to claim 13, wherein the first transistors of the first subword drivers, the second transistors of the second subword drivers, and the bridge transistors are n-channel type transistors.

15. The apparatus according to claim 13, wherein
the first straight common gate is coupled to a first main word line,
the second straight common gate is coupled to a second main word line, and
each of the plurality of independent gates is configured to receive a gate control signal complementary to a word driver signal of the first and second subword drivers.

16. The apparatus according to claim 13, wherein
the first straight common gate, the second straight common gate, and the independent gates are in a polysilicon gate layer, and
the independent gates are separated from one another by a cut portion in the polysilicon gate layer.

17. An apparatus, comprising:
a first transistor area including:
a first common gate for a plurality of first-conductivity type transistors of first subword drivers; and
a second common gate for a plurality of first-conductivity type transistors of second subword drivers; and
a second transistor area including:
a third straight common gate for a plurality of second-conductivity type transistors of the first subword drivers, the third straight common gate extending straight in a first horizontal direction;
a fourth straight common gate for a plurality of second-conductivity type transistors of the second subword drivers, the fourth straight common gate extending straight in the first horizontal direction and arranged in parallel with the third straight common gate in a second horizontal direction perpendicular to the first horizontal direction; and
a plurality of independent gates for a plurality of bridge transistors, the plurality of independent gates arranged in line between the third straight common gate and the fourth straight common gate.

18. The apparatus according to claim 17, wherein
the first-conductivity type transistors are p-channel type transistors,
the second-conductivity type transistors are n-channel type transistors, and
the bridge transistors are n-channel type transistors.

19. The apparatus according to claim 17, wherein
the first common gate for the first-conductivity type transistors of the first subword drivers and the third straight common gate for the second-conductivity type transistors of the first subword drivers are coupled to each other in a row in the first horizontal direction via a first interconnect layer, the first common gate and the third straight common gate coupled to a first main word line via a first gate contact,
the second common gate for the first-conductivity type transistors of the second subword drivers and the fourth straight common gate for the second-conductivity type transistors of the second subword drivers are coupled to each other in another row in the first horizontal direction via a second interconnect layer, the second common gate and the fourth straight common gate coupled to a second main word line via a second gate contact, and
the plurality of independent gates are coupled to gate control lines via third gate contacts.

20. The apparatus according to claim 19, wherein
the first common gate and the third straight common gate are configured to receive a first main word signal via the first main word line,
the second common gate and the fourth straight common gate are configured to receive a second main word signal via the second main word line, and
each of the plurality of independent gates is configured to receive a gate control signal complementary to a word driver signal of the first and second subword drivers via a corresponding one of the gate control lines.
